(19) United States
(12) Patent Application Publication
(10) Pub. No.: US 2025/0207292 A1
(43) Pub. Date: Jun. 26, 2025

(54) APPARATUS FOR PROCESSING SUBSTRATE, METHOD OF CONTROLLING APPARATUS FOR PROCESSING SUBSTRATE, AND STORAGE MEDIUM WITH PROGRAM STORED THEREIN

(71) Applicant: EBARA CORPORATION, Tokyo (JP)

(72) Inventors: Ryuya KOIZUMI, Tokyo (JP); Shunsuke KAGAYA, Tokyo (JP); Shaunak GHATPANDE, Tokyo (JP)

(21) Appl. No.: 18/970,366

(22) Filed: Dec. 5, 2024

(30) Foreign Application Priority Data
Dec. 21, 2023 (JP) 2023-215584

(51) Int. Cl. C25D 21/12; G05B 19/418

(52) U.S. Cl. CPC C25D 21/12; G05B 19/41865

(57) ABSTRACT

An apparatus for processing a substrate is configured to generate a transfer schedule by adding a positive or negative margin time to a processing time of a first process set in a recipe, wherein the margin time is calculated by a learning network or a statistical calculation method using actually measured processing times obtained by actually performing the first process with regard to a plurality of substrates in a first processing tank. In addition to or in place of this configuration, the apparatus may be configured to estimate an estimated process end time from a detection value obtained from a sensor, and when it is determined that the estimated process end time is behind a scheduled transfer start time, to correct the scheduled transfer start time to the estimated process end time and adjust the transfer schedule in accordance with the corrected scheduled transfer start time.

### TECHNICAL FIELD

The present disclosure relates to an apparatus for processing a substrate, a method of controlling the apparatus for processing the substrate, and a storage medium with a program stored therein and configured to cause a computer to perform the method of controlling the apparatus for processing the substrate.

### BACKGROUND ART

As one of improvement policies of plating performance, an electrolytic plating apparatus is likely to require adjustment of a plating end timing based on measurement values of plating film thickness, in order to reduce a variation in plating film thickness among respective substrates (for example, wafers). This is because even an identical set plating current is likely to provide different plating film-forming rates, depending on individual differences of modules, individual differences of substrates, and differences of chemical component.

A conventional transfer scheduler is configured to generate in advance a substrate transfer schedule based on a plating process time specified in advance in a recipe (time set in a recipe) and then perform processing of substrates. This specification is on the premise of no variation in actual time required for the plating process. In the case where the actual required time is varied, however, substrates cannot be transferred according to the substrate transfer schedule generated in advance. This is likely to cause a leaving time after processing in a processing module (a time period for which a wafer after a plating processing is soaked in a plating solution before being unloaded) to exceed a limit value, due to the disturbance of transfer. This problem is not limited to plating but may occur in other substrate processings.

Techniques described in PTL 1 to PTL 3 are exemplified prior art methods of adjusting the transfer schedule. PTL 1 describes a control of performing rescheduling when a process end time of a processing unit is detected and a remaining time to uploading is equal to or longer than a time period required for rescheduling. PTL 2 describes a configuration of storing an actually measured processing time of a lot processed last in a semiconductor manufacturing apparatus in correlation to a data tag (array of recipe) and estimating a processing time of a lot that is to be processed next, based on the stored actually measured processing time. PTL 3 describes a configuration of performing time adjustment of a tentative schedule as a block by rescheduling and then regenerating an overall schedule.

### CITATION LIST

### Patent Literatures

PTL 1: Japanese Unexamined Patent Publication No. 2022-181368
PTL 2: Japanese Unexamined Patent Publication No. 2011-018738
PTL 3: Japanese Unexamined Patent Publication No. 2021-36582

### SUMMARY OF INVENTION

### Technical Problem

The prior art methods of adjusting the transfer schedule have, however, not taken into account the situation that the actual process end time of the substrate is behind a process end time set in a recipe and that a leaving time after processing in a processing module (a time period when the substrate is left in a processing solution or in a processing module, after completion of the processing until unloading) exceeds a limit value due to the disturbance of transfer.

One object of the present disclosure is to solve at least one of the problems described above. One object of the present disclosure is to suppress or prevent the leaving time after processing from exceeding the limit value even in the case where the process end time varies.

### Solution to Problem

According to one aspect of the present disclosure, there is provided an apparatus for processing a substrate, comprising: a plurality of processing tanks, each being configured to perform processing of a substrate; a transfer machine configured to transfer the substrate; and a controller configured to generate a transfer schedule, which causes the substrate to be transferred between the plurality of processing tanks and to be processed, and configured to control the transfer of the substrate by the transfer machine and control the processing of the substrate in each of the plurality of processing tanks, based on the transfer schedule, wherein the plurality of processing tanks include a first processing tank configured such that one or a plurality of processes including a first process are performed for the substrate therein, and the controller adds a positive or negative margin time to a processing time of the first process that is set in a recipe to generate the transfer schedule, wherein the margin time is calculated by a learning network or a statistical calculation method using actually measured processing times obtained by actually performing the first process with regard to a plurality of substrates in the first processing tank.

According to one aspect of the present disclosure, there is provided an apparatus for processing a substrate, comprising: a plurality of processing tanks, each being configured to perform processing of a substrate; a transfer machine configured to transfer the substrate; and a controller configured to generate a transfer schedule, which causes the substrate to be transferred between the plurality of processing tanks and to be processed, and configured to control the transfer of the substrate by the transfer machine and control the processing of the substrate in each of the plurality of processing tanks, based on the transfer schedule, wherein the plurality of processing tanks include a first processing tank, which is configured such that one or a plurality of processes including a first process are performed for the substrate therein and which is provided with a sensor configured to detect a degree of progress of the first process, and the controller estimates an estimated process end time, which is a time point when all the one or the plurality of processes performed in the first processing tank are terminated, from a detection value obtained from the sensor, and when it is determined that the estimated process end time is behind a scheduled transfer start time set in the transfer schedule, corrects the scheduled transfer start time to the estimated process end time and adjusts the transfer schedule in accordance with the corrected scheduled transfer start time.

### BRIEF DESCRIPTION OF DRAWINGS

FIG. 1 is a diagram illustrating the general layout of a substrate processing apparatus according to one embodiment;

FIG. 2 is an explanatory diagram illustrating the control configuration of the substrate processing apparatus;

FIG. 3 is an explanatory diagram illustrating the more detailed control configuration of the substrate processing apparatus;

FIG. 4A is a diagram illustrating one example of a transfer schedule in a plating tank;

FIG. 4B is a diagram illustrating the example of the transfer schedule in the plating tank;

FIG. 5 is a flowchart showing a general process of transfer scheduling;

FIG. 6 is a flowchart showing a process of generating an adjusted transfer schedule;

FIG. 7 is a flowchart showing a process of reinserting a first part of the transfer schedule for an object substrate after takeout from a plating tank, into an overall transfer schedule;

FIG. 8 is a flowchart showing a process of reinserting a second part of the transfer schedule for a non-transferred portion of substrate(s) on an upstream side that are affected by transfer of the object substrate, into the overall transfer schedule;

FIG. 9A is a transfer time table showing a transfer schedule generated first;

FIG. 9B is a transfer time table showing a transfer schedule with exclusion of a first part of the transfer schedule for an object substrate after takeout from a plating tank, a second part of the transfer schedule for a non-transferred portion of substrate(s) on an upstream side that are affected by the object substrate, and a third part of the transfer schedule for subsequent unprocessed substrates;

FIG. 9C is a transfer time table showing a transfer schedule with reinsertion of the first part of the transfer schedule for the object substrate after takeout from the plating tank;

FIG. 9D is a transfer time table showing a transfer schedule with additional reinsertion of the second part of the transfer schedule for the non-transferred portion of the substrate(s) on the upstream side that are affected by the object substrate; and

FIG. 9E is a transfer time table showing a transfer schedule with additional reinsertion of the third part of the transfer schedule for the subsequent unprocessed substrates.

### DESCRIPTION OF EMBODIMENTS

The following describes one embodiment of the present disclosure with reference to the drawings. In the respective embodiments described below, identical or equivalent members are expressed by identical reference signs with omission of duplicated description. In the description hereof, the expressions such as “upper” or “upward”, “lower” or “downward”, “left” or “leftward” and “right” and “rightward” are used. These expressions indicate the positions, the orientations, and the directions on the sheet surface of the illustrated drawings for the purpose of explanation, and these positions, orientations and directions may be different from those in the actual arrangement, for example, when using the apparatus.

### <General Configuration>

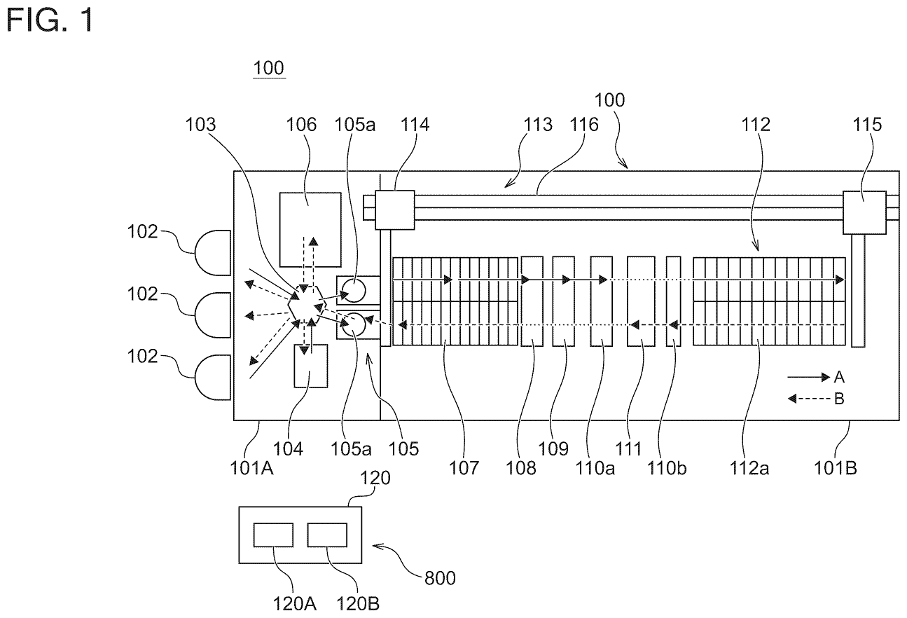

FIG. 1 is a diagram illustrating the general layout of a substrate processing apparatus according to one embodiment of the present disclosure. In this embodiment, a substrate processing apparatus 100 is an electrolytic plating apparatus. The embodiment illustrates a dip type electrolytic plating apparatus as an example. The present disclosure is, however, applicable to any plating apparatuses (cup type/face-down type plating apparatuses, non-electrolytic plating apparatuses and the like) and is also applicable to any other substrate processing apparatuses.

The substrate processing apparatus 100 is roughly divided into a loading/unloading station 101A configured to load a substrate as an object to be processed to a substrate holder (not shown) or to unload the substrate from the substrate holder; and a processing station 101B configured to process the substrate by one or a plurality of processes. The substrate herein includes circular substrates, rectangular substrates (polygonal substrates such as quadrilateral substrates) and substrates in other arbitrary shapes. The substrate herein denotes any object to be processed and includes semiconductor wafers, glass substrates, liquid crystal substrates, printed circuit boards, and other arbitrary substrates.

The loading/unloading station 101A includes a plurality of cassettes 102 placed on a plurality of cassette tables, an aligner 104, a substrate attachment/detachment station 105, and a spin rinse dryer 106. The cassette 102 is a substrate container (for example, FOUP) configured to place a substrate therein. The aligner 104 is configured to, for example, adjust a reference position such as an orientation flat or a notch to a predetermined direction. The substrate attachment/detachment station 105 includes one or a plurality of substrate attachment/detachment devices 105a configured to attach a substrate to a substrate holder and to detach the substrate from the substrate holder. The spin rinse dryer 106 is configured to rotate a substrate after a plating process at a high speed and dry the substrate while supplying a rinse solution to the substrate after the plating process. A transfer robot 103 configured to transfer the substrate between these units is placed at the center of these units.

The processing station 101B includes a stocker 107 configured to store and temporarily place substrate holders, a pre-wet module 108, a pre-soak module 109, a pre-soak rinse module 110a, a rinse module 110b, a blow module 111, and a plating process module 112. Any one of or all of the pre-wet module 108, the pre-soak module 109, the pre-soak rinse module 110a, the rinse module 110b, the blow module 111, and the plating process module 112 may be referred to as the processing module(s). Part or all of the processing modules out of the pre-wet module 108, the pre-soak module 109, the pre-soak rinse module 110a, the rinse module 110b, the blow module 111, and the plating process module 112 has a processing tank that keeps a predetermined processing solution therein.

In the pre-wet module 108, the substrate is soaked in a processing solution (for example, pure water), and the air inside of an opening on the surface of the substrate is replaced with pure water. In the pre-soak module 109, an oxide film on the surface of a conductive layer, such as a seed layer, formed on the surface of the substrate is etched off. In the pre-soak rinse module 110a, the substrate after pre-soaking, together with the substrate holder, is cleaned with a cleaning liquid (for example, pure water) as a processing solution. In the rinse module 110b, the substrate after plating, together with the substrate holder, is cleaned with a cleaning liquid as a processing solution. The blow module 111 serves to drain the liquid from the substrate after cleaning.

The plating process module 112 includes a plurality of cells (also called plating tanks 112a) provided with an overflow tank. Each of the plating tanks 112a places, for example, one substrate inside thereof and causes the substrate to be soaked in a plating solution kept inside thereof, so that the surface of the substrate is plated with, for example, copper. The type of the plating solution used herein is not specifically limited but may be any of various plating solutions according to the applications. In the case where one substrate is subjected to a plurality of different plating processes, the plating process module 112 has a plurality of plating tanks 112a that respectively keep different types of plating solutions inside thereof. According to one embodiment, a rinse process (described later) after the plating process is performed in the plating tank 112a.

The substrate processing apparatus 100 is provided with a substrate holder transfer device 113 that employs, for example, a linear motor system and that is placed on the side of the above modules and devices and is configured to transfer the substrate holder between these modules and devices. This substrate holder transfer device 113 includes a transfer machine (transporter) 114 and a transfer machine (transporter) 115. The transfer machine 114 and the transfer machine 115 run on a rail 116. A modification may be provided with only one of the transfer machines 114 and 115 and may be configured to transfer the substrate between the respective modules and devices described above by one transfer machine 114. Another modification may be provided with three or more transfer machines. The above configuration of the substrate processing apparatus 100 is only illustrative, and any other configuration may be employed.

In the substrate processing apparatus 100, the transfer robot 103 takes out an unprocessed substrate from the cassette 102 and places the substrate on the aligner 104. The aligner 104 positions the substrate, on the basis of the reference position, such as an orientation flat or a notch. The transfer robot 103 subsequently transfers the substrate to the substrate attachment/detachment device 105a to attach the substrate to a substrate holder taken out from the stocker 107. In the illustrated example, the two substrate attachment/detachment devices 105a respectively attach the substrates to the respective substrate holders and transfers the two substrate holders as one set. The substrate attached to the substrate holder is transferred by the transfer machine 114 to the pre-wet module 108 to be subjected to a pre-water washing process, is subsequently transferred to the pre-soak module 109 to be subjected to a pretreatment process, and is further transferred to the pre-soak rinse module 110a to be subjected to a water washing process.

The substrate subjected to the water washing process in the pre-soak rinse module 110a is transferred by the transfer machine 115 to one of the plating tanks 112a of the plating process module 112 and is soaked in the plating solution. The substrate is accordingly subjected to a plating process, and a metal film is formed on the substrate. In the case where the substrate is to be processed by multiple different plating processes, the substrate is sequentially transferred to a plurality of plating tanks 112s to be subjected to the respective plating processes. The substrate after the plating process is transferred by the transfer machine 115 to the rinse module 110b to be subject to a water washing process and is then transferred to the blow module 111 to be subjected to a rough drying process. The substrate is subsequently transferred by the transfer machine 114 to the substrate attachment/detachment station 105 and is detached from the substrate holder. The substrate detached from the substrate holder is transferred by the transfer robot 103 to the spin rinse dryer 106 to be subjected to a cleaning and drying process and is then loaded to the cassette 102.

### <Control Configuration>

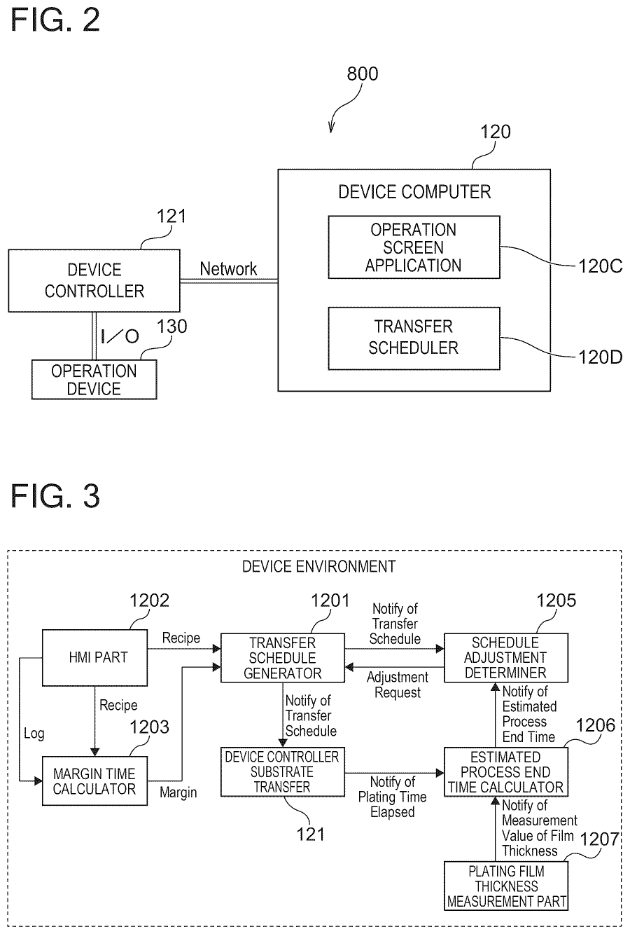

FIG. 2 is an explanatory diagram illustrating the control configuration of the substrate processing apparatus 100.

The substrate processing apparatus 100 includes a device computer 120 and a device controller 121, which serve as a controller 800 configured to control the respective parts of the apparatus. The device computer 120 is connected with the device controller 121 via a wired or wireless network, a cable or the like. Various operation devices 130 of the substrate processing apparatus 100 are connected with the device controller 121 via a predetermined interface I/O. The device computer 120 and the device controller 121 cooperate with each other to perform controls of the various operation devices 130 of the substrate processing apparatus 100. Control signals from the device computer 120 are sent to the device controller 121 via the network, so as to control the various operation devices 130 via the device controller 121. The device computer 120 is configured to be communicable by wire or wirelessly with a non-illustrated upper level controller (host computer) that comprehensively controls the substrate processing apparatus 100 and other relevant apparatuses and to exchange data with a database of the upper level controller.

The device controller 121 is configured by, for example, a PLC, a sequencer or the like to control the various operation devices 130 of the substrate processing apparatus 100, based on control commands, set parameters, a transfer schedule (transfer time table) and the like given from the device computer 120. The various operation devices of the substrate processing apparatus 100 herein include the transfer robots 103, the transfer machines (transporters) 114 and 115, and other devices.

The device computer 120 includes a memory 120B configured to store therein a variety of set data and a variety of programs; and a CPU 120A configured to execute the programs in the memory 120B (shown in FIG. 1). The device computer 120 may be provided with an input/output interface that includes an output device, such as a display, and an input device including a keyboard, a mouse and the like, although not specifically illustrated. A storage medium that configures the memory 120B may include any volatile storage medium and/or any non-volatile storage medium. The storage medium may include one or a plurality of arbitrary storage media, for example, a ROM, a RAM, a hard disk, a CD-ROM, a DVD-ROM, and a flexible disk.

The programs stored in the memory 120B include software that configures an operation screen application 120C; and scheduling software that configures a module called a transfer scheduler 120D. The scheduling software herein is scheduling software configured to compute a substrate transfer schedule and is executed by the CPU 120A to configure the transfer scheduler 120D (the transfer scheduler 120D is configured by the CPU 120A executing the scheduling software). The transfer scheduler 120D generates a transfer schedule for performing transfer control that provides a maximum throughput, based on, for example, a predetermined operation time of each of the transfer machines and the like and process conditions (a process recipe: hereinafter simply referred to as recipe) of a target substrate for which an instruction to be processed is received. A graph network-type scheduler, a simulation-type scheduler, a machine learning-type scheduler, or another arbitrary-type scheduler may be employed as the scheduling software/the transfer scheduler 120D. The operation screen application 120C shows, for example, the recipe, a transfer schedule described later, and the like, on the display. This operation screen application 120C also enables inputs from an operator to be received and accepted.

In one example, the transfer scheduler 120D receives inputs of a recipe, parameters other than the recipe, a margin time described later, and constraint conditions as input data and generates a transfer schedule/transfer time table at a maximum throughput while satisfying the constraint conditions. The inputs of the recipe, the parameters other than the recipe and the constraint conditions may be stored in the memory 120B. The recipe may be input by the user or may be selected by the user. The constraint conditions herein include an upper limit of a leaving time of a substrate after processing in each of the processing tanks (a limit value of the leaving time after processing) and a buffer region set for the purpose of avoiding a collision between transfer machines. The upper limit of the leaving time after processing denotes a time constraint set to prevent corrosion of a substrate in each of the processing tanks and is defined as a time period until the substrate is unloaded from the processing tank after completion of processing in the processing tank. The buffer region is an area set for each transporter (transfer machine) in order to prevent a collision between the transfer machines 114 and 115 and is set to prevent any other transporter from moving to a buffer region of each transporter and thereby prevent the respective transporters from approaching each other within a predetermined distance.

The recipe includes, for example, the number of substrates to be processed, an order of processing, a processing time and the like, which are set for each substrate or set for each job that is allocated to one or a plurality of substrates. The parameters other than the recipe include, for example, “set parameters of the apparatus”, “set parameters of the processing module/tank” and “set parameters of the transfer machine”. The set parameters of the apparatus include, for example, parameters indicating the use/non-use of each tank, the number of tanks, the number of substrate holders, and the like. The set parameters of the processing module/tank include, for example, an operation time of each of various mechanisms and the like included in the processing module/tank, a pretreatment time/post treatment time, a reset time and the like. The pretreatment time denotes a time period until a start of processing after loading of the substrate into the tank. The post treatment time denotes a time period until unloading of the substrate is allowed after processing of the substrate in the tank. The reset time denotes a time period until a tank becomes usable again after unloading of the substrate from the tank. The set parameters of the transfer machine include, for example, a moving time, a takeout/storage time and the like. This configuration of the input parameters is only illustrative and can be appropriately changed according to the configurations of the apparatus and the processes.

The transfer schedule/transfer time table (output data) generated by the transfer scheduler 120D includes, for example, a start time, a transfer machine to be operated, type of an operation (takeout/storage), a unit processing module/tank as a source of moving, and a processing module/tank as a destination of moving. The configuration of the transfer schedule/transfer time table is only illustrative and can be appropriately changed according to the configurations of the apparatus and the processes.

The programs stored in the memory 120B further include, for example, a program for controlling attachment and detachment of a substrate to and from a substrate holder in the substrate attachment/detachment station 105; a program for controlling processing of a substrate in each of the processing modules/tanks (including a program for controlling a plating process in the plating process module 112); and other programs for controlling the respective parts of the substrate processing apparatus.

FIG. 3 is an explanatory diagram illustrating the more detailed control configuration of the substrate processing apparatus.

As shown in FIG. 3, the device computer 120 includes a transfer schedule generator 1201 serving as the transfer scheduler 120D, an HMI part 1202, a margin time calculator 1203, a schedule adjustment determiner 1205, and an estimated process end time calculator 1206.

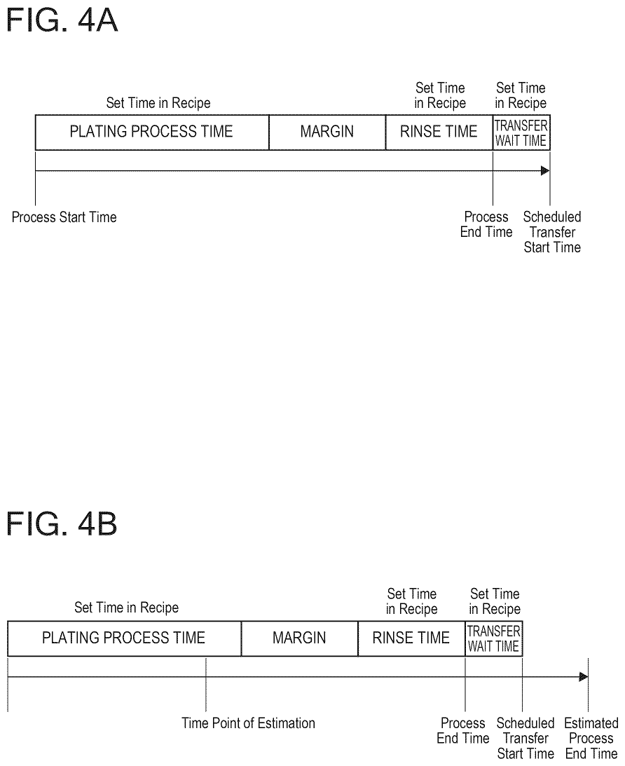

According to the embodiment, the transfer schedule generator 1201 (the transfer scheduler 120D) generates a transfer schedule, based on set values of the recipe, the parameters other than the recipe, the constraint conditions and the like, a margin time calculated by the margin time calculator 1203 (as shown in FIG. 4A and FIG. 4B) and the like. The transfer schedule generator 1201 also adjusts the transfer schedule, in response to an adjustment request from the schedule adjustment determiner 1205. Furthermore, the transfer schedule generator 1201 notifies the device controller 121 of a transfer schedule whenever the transfer schedule is generated (including generation of an adjusted transfer schedule by adjustment).

The HMI part 1202 receives and accepts the user's setting or selection of a recipe via an input-output interface/human machine interface (HMI) and outputs the recipe that is to be used for processing of the substrate to the transfer schedule generator 1201 and to the margin time calculator 1203. The HMI part 1202 also collects logs of the processing in the substrate processing apparatus 100 (set values of the recipe used for the processing, measurement values of a plating current, a plating film thickness and the like, an actually measured plating process time, and various other pieces of processing information) and gives the collected logs to the margin time calculator 1203.

The margin time calculator 1203 calculates a margin time, based on the recipe and the logs given from the HMI part 1202, such that the actually measured plating processing time does not exceed a total time of the plating process time set in the recipe and the margin time (adjusted plating process time) with regard to most substrates (for example, substrates in a range of ασ in statistical data of a plurality of substrates actually plated in the past, where σ denotes a standard deviation and α denotes a multiple).

The estimated process end time calculator 1206 calculates an “estimated plating end time” of a plating process, based on a plating time elapsed obtained from the device controller 121 and a measurement value of film thickness of a plating film obtained from a plating film thickness measurement part 1207 during the plating process of a substrate, and then calculates an “estimated process end time” in a plating tank, based on the “estimated plating end time”. In the case where only a plating process is performed in the plating tank 112a, the “estimated plating end time” is equal to the “estimated process end time”. In the case where a plating process and a rinse process after the plating process are performed in the plating tank 112a (as shown in FIG. 4A and FIG. 4B), the “estimated plating end time”+“rinse time” is equal to the “estimated process end time”.

The plating film thickness measurement part 1207 is, for example, a film thickness gauge placed in each of the plating tanks 112a. For example, an optical displacement sensor (utilizing reflected wave or the like) may be employed for the film thickness gauge.

The schedule adjustment determiner 1205 determines whether adjustment of the current transfer schedule is required or not, based on the transfer schedule obtained from the transfer schedule generator 1201 and the estimated process end time obtained from the estimated process end time calculator 1206. When the schedule adjustment determiner 1205 determines that adjustment of the transfer schedule is required, the schedule adjustment determiner 1205 outputs an adjustment request for the transfer schedule to the transfer schedule generator 1201. The schedule adjustment determiner 1205 determines that adjustment of the current transfer schedule is required in the case where the estimated process end time is behind a scheduled transfer start time (transfer (unloading) start time when the substrate is taken out from the plating tank 112a) in the current transfer schedule as shown in FIG. 4B. The schedule adjustment determiner 1205 also determines that adjustment of the current transfer schedule is required when it is determined, at the end of the processing in the plating tank 112a (the plating process or the plating process+rinse process), that the actual process end time is beyond the scheduled transfer start time in the current transfer schedule.

### <Transfer Schedule>

FIG. 4A and FIG. 4B illustrate an example of the transfer schedule (transfer time table) in the plating tank 112a. As shown in FIG. 4A, the transfer schedule in the plating tank 112a includes, for example, a plating process time (a set time in the recipe), a margin time, a rinse time (a set time in the recipe), a transfer wait time (a set time in the recipe), a process start time, a process end time, and a scheduled transfer start time. FIG. 4A and FIG. 4B show an example of performing the plating process and the rinse process in the plating tank 112a. The rinse process may, however, be omitted. The transfer wait time may not be set in part or the entirety of the transfer schedule.

When the estimated process end time calculator 1206 receives a notification of a measurement value of film thickness from the plating film thickness measurement part 1207 at an estimation time shown in FIG. 4B, the estimated process end time calculator 1206 calculates an estimated plating end time, based on the plating time elapsed and the measurement value of film thickness according to a rule-based calculation formula, a learning network or the like. The rule-based calculation formula is a theoretical calculation formula and/or a calculation formula derived from an experiment or the like. The estimated process end time calculator 1206 also calculates an estimated process end time (estimated plating end time+rinse time), based on the estimated plating end time. In the case where the estimated process end time is behind the scheduled transfer start time as shown in FIG. 4B, the schedule adjustment determiner 1205 determines that adjustment of the transfer schedule is required and outputs an adjustment request for the transfer schedule to the transfer schedule generator 1201. In response to this adjustment request, the transfer schedule generator 1201 performs a process of correcting the scheduled transfer start time of the substrate involved (referred to as the object substrate) from the plating tank 112a in the current transfer schedule to the estimated process end time, so as to adjust the current transfer schedule and generate an adjusted transfer schedule.

As described later, when it is determined, after the end of the processing, that an actual process end time is beyond the scheduled transfer start time, the schedule adjustment determiner 1205 also determines that adjustment of the transfer schedule is required and outputs an adjustment request for the transfer schedule to the transfer schedule generator 1201. In response to this adjustment request, the transfer schedule generator 1201 performs a process of correcting the scheduled transfer start time of the substrate involved (referred to as the object substrate) from the plating tank 112a in the current transfer schedule to a time determined by adding a predetermined time period to the actual process end time, so as to adjust the current transfer schedule and generate an adjusted transfer schedule.

### <Flow of Transfer Scheduling>

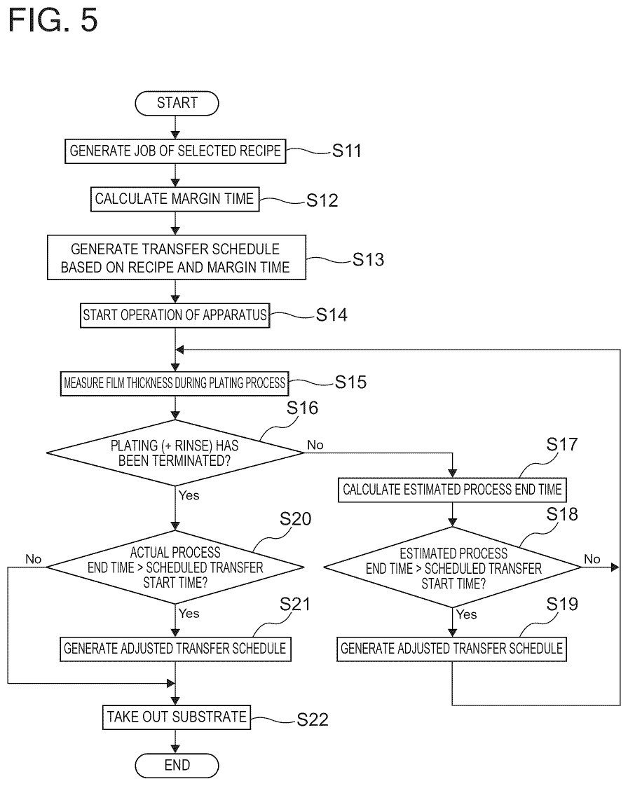

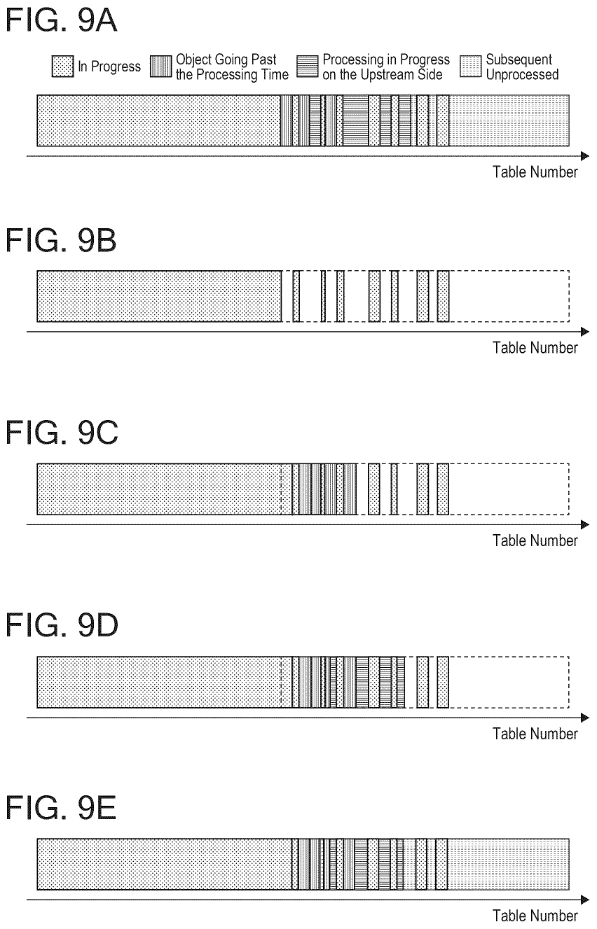

FIG. 5 is a flowchart showing a general process of transfer scheduling. FIG. 9A to FIG. 9E are explanatory diagrams illustrating adjustment of a transfer schedule.

FIG. 9A is a transfer time table showing a transfer schedule generated first. FIG. 9B is a transfer time table showing a transfer schedule with exclusion of a first part of the transfer schedule for an object substrate going past a processing time after takeout from a plating tank, a second part of the transfer schedule for a non-transferred portion of substrate(s) on an upstream side that are affected by the object substrate, and a third part of the transfer schedule for subsequent unprocessed substrates. FIG. 9C is a transfer time table showing a transfer schedule with reinsertion of the first part of the transfer schedule for the object substrate after takeout from the plating tank. FIG. 9D is a transfer time table showing a transfer schedule with additional reinsertion of the second part of the transfer schedule for the non-transferred portion of the substrate(s) on the upstream side that are affected by the object substrate. FIG. 9E is a transfer time table showing a transfer schedule with additional reinsertion of the third part of the transfer schedule for the subsequent unprocessed substrates.

In FIG. 9A to FIG. 9E, a table number denotes a number allocated to each of processes (including a transfer process) and increases with elapse of time. The table number is unequivocally allocated to each of transfers. Even when a plurality of substrates that are concurrently in progress are transferred by different transfer machines at a perfectly identical timing, the respective substrates have different table numbers. When a plurality of transfer machines have an identical transfer start time, the transfers of respective table numbers are continuously started within an extremely short time period and are thus deemed to be started substantially simultaneously. In these drawings, “in progress” indicates the transfer schedule for the substrates taken out from the cassette(s) with exclusion of the first part and the second part; “object going past the processing time” indicates the first part of the transfer schedule; “processing in progress on the upstream side” indicates the second part of the transfer schedule; and “subsequent unprocessed” indicates the third part of the transfer schedule. The details will be described later.

In the description below, the “transfer schedule” and the “transfer time table” are used as synonyms.

In the flowchart of FIG. 5, at step S11, a job of a selected recipe is generated with regard to a plurality of substrates (placed in one identical cassette or in a plurality of cassettes).

At step S12, the margin time calculator 1203 calculates a margin time with respect to a plating process time (a set time in the recipe). The margin time is calculated as a time period when most substrates (for example, substrates in a range of 36) can complete the plating process within the plating process time (the set time in the recipe)+margin time. An estimated plating process time is calculated as the plating process time (the set time in the recipe)+margin time.

At step S13, the transfer schedule generator 1201 generates a transfer schedule, based on set values of the recipe, the parameters other than the recipe, the constraint conditions and the like and the margin time (as shown in FIG. 9A).

At step S14, the operation of the substrate processing apparatus 100 is started, based on the generated transfer schedule.

At step S15, during a plating process of a substrate in the plating tank 112a, the plating film thickness measurement part 1207 measures the film thickness of a plating film formed on the substrate and outputs a measurement value of film thickness of the plating film to the estimated process end time calculator 1206.

At step S16, it is determined whether the processing in the plating tank 112a (plating process+rinse process in the illustrated example of FIG. 4A and FIG. 4B) has been terminated. In the case where the rinse process is not performed in the plating tank 112a, termination of the processing in the plating tank 112a means termination of the plating process. When it is determined at step S16 that the processing in the plating tank 112a has not yet been terminated (step S16: No), the processing flow proceeds to step S17.

At step S17, the estimated process end time calculator 1206 calculates the “estimated plating end time” of the plating process, based on the plating time elapsed obtained from the device controller 121 and the measurement value of film thickness of the plating film obtained from the plating film thickness measurement part 1207 during the plating process of the substrate, and then calculates the “estimated process end time” in the plating tank, based on the “estimated plating end time”.

In the case where only a plating process is performed in the plating tank 112a, the “estimated plating end time” is equal to the “estimated process end time”. In the case where a plating process and a rinse process after the plating process are performed in the plating tank 112a (as shown in FIG. 4A and FIG. 4B), the “estimated plating end time”+“rinse time” is equal to the “estimated process end time”.

At step S18, the schedule adjustment determiner 1205 determines whether the estimated process end time is behind the scheduled transfer start time. When it is determined that the estimated process end time is not behind the scheduled transfer start time (step S18: No), the processing flow returns to step S15 and repeats the processing of and after step S15. When it is determined that the estimated process end time is behind the scheduled transfer start time (step S18: Yes: as shown in FIG. 4B), on the other hand, the processing flow proceeds to step S19 to perform adjustment of the transfer schedule and generate an adjusted transfer schedule (as shown in FIG. 9B to 9E).

When it is determined at step S16 that the processing in the plating tank 112a has been terminated (step S16: Yes), the processing flow proceeds to step S20.

At step S20, the schedule adjustment determiner 1205 determines whether the actual process end time of the processing in the plating tank 112a (i.e., a time point when the processing was actually terminated) is beyond the scheduled transfer start time. When it is determined that the actual process end time of the processing in the plating tank 112a is not beyond the scheduled transfer start time (step S20: No), the processing flow proceeds to step S22 to unload the substrate from the plating tank 112a at the scheduled transfer start time. When it is determined that the actual process end time of the processing in the plating tank 112a is beyond the scheduled transfer start time (step S20: Yes), on the other hand, the processing flow proceeds to step S21 to adjust the transfer schedule and generate an adjusted transfer schedule (as shown in FIG. 9B to FIG. 9E). The adjusted transfer schedule is also called the transfer schedule after the adjustment or the readjusted transfer schedule.

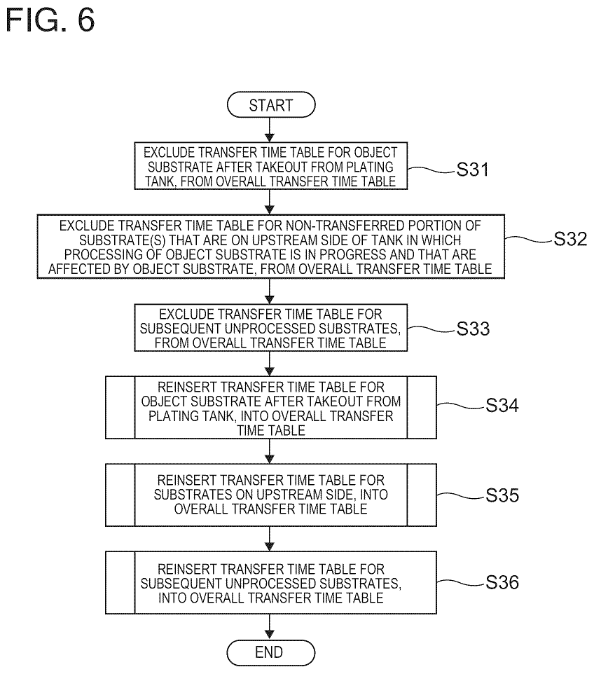

FIG. 6 is a flowchart showing a process of generating the adjusted transfer schedule. This process is commonly performed at step S19 and at step S21 in FIG. 5.

At step S31, the processing flow excludes the first part of the transfer schedule for the substrate determined that the estimated process end time (S18) or the actual process end time (S20) thereof is behind or is beyond the scheduled transfer start time (this substrate is referred to as the object substrate or the substrate of determination object), after takeout from the plating tank, from the current transfer schedule (overall transfer schedule) (as shown in FIG. 9B).

At step S32, the processing flow excludes the second part of the transfer schedule for a non-transferred portion of substrate(s) that are on the upstream side of the plating tank in which the processing of the object substrate is in progress and that are affected by transfer of the object substrate, from the overall transfer schedule (as shown in FIG. 9B). The (adjustable) transfer schedule for a non-transferred portion of one or a plurality of substrates that are on the upstream side in the transfer sequence of the plating tank in which the processing of the object substrate is in progress and that are affected by transfer of the object substrate (for example, substrates that are scheduled to be processed in the same plating tank), out of one or a plurality of substrates taken out from the cassette(s) is accordingly excluded from the overall transfer schedule. With regard to a substrate for which the processing in a module/tank is in progress, a transfer schedule for this substrate after takeout from this module/tank is to be excluded. With regard to a substrate for which transfer between modules/tanks is in progress, a transfer schedule for this substrate after takeout from a module/tank as a transfer destination is to be excluded.

In this illustrated example, the transfer sequence is the order of (the cassette 102), the aligner 104, the substrate attachment/detachment device 105a, the pre-wet module 108, the pre-soak module 109, the pre-soak rinse module 110a, the plating tank 112a, the rinse module 110b, the blow module 111, the substrate attachment/detachment station 105, the spin rinse dryer 106, and the cassette 102 as described above. The upstream side of the object substrate in the plating tank 112a corresponds to the range from the aligner 104, the substrate attachment/detachment device 105a, the pre-wet module 108, the pre-soak module 109 to the pre-soak rinse module 110a (before the plating tank 112a in the arrow A shown in FIG. 1).

The substrates on the upstream side that are affected by the transfer of the object substrate include, for example, substrates on the upstream side that are scheduled to use the same plating tank 112a as that used for processing of the object substrate. Even substrates on the upstream side that are scheduled not to use the same plating tank 112 as that used for processing of the object substrate may, however, be affected by the transfer of the object substrate on the upstream side, depending on the configuration of the upstream side (for example, the number of tanks in the pre-wet module 108). The substrates on the upstream side that are affected by the transfer of the object substrate may also include such substrates.

At step S33, the processing flow excludes the third part of the transfer schedule for subsequent unprocessed substrates, from the overall transfer schedule (as shown in FIG. 9B). The subsequent unprocessed substrates herein denote subsequent unprocessed substrates that have not yet been taken out from the cassette(s) 102 (that are still placed in the cassette(s) 102).

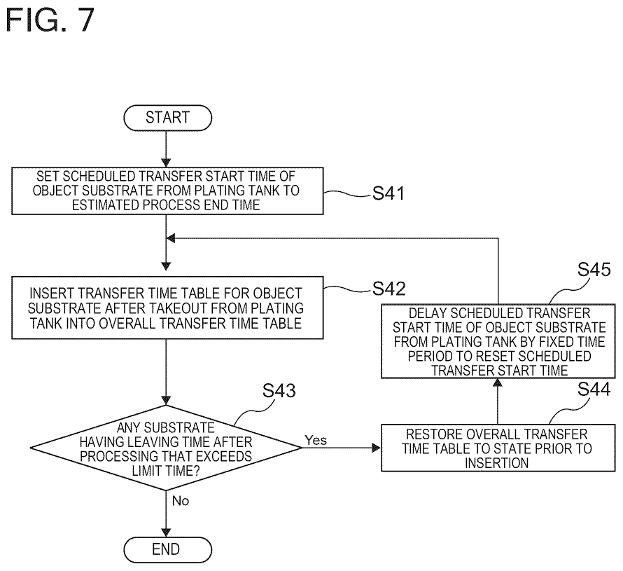

At step S34, the processing flow reinserts the first part of the transfer schedule for the object substrate after takeout from the plating tank, into the overall transfer schedule (as shown in FIG. 9C) by a processing flow described later with reference to FIG. 7.

At this step, the first part of the transfer schedule for the object substrate after takeout from the plating tank is re-embedded between transfer schedules for other substrates in the overall transfer schedule, in accordance with the estimated process end time (S18) of the object substrate in the plating tank 112a or in accordance with the time determined by adding a predetermined time period to the actual process end time (S20) of the object substrate in the plating tank 112a. More specifically, as described later with reference to FIG. 7, the processing flow corrects the scheduled transfer start time of the object substrate in the plating tank 112a to the estimated process end time (S18) or to the time determined by adding a predetermined time period to the actual process end time (S20), and reinserts the first part of the transfer schedule for the object substrate after takeout from the plating tank, into the overall transfer schedule, while adjusting the overall transfer schedule based on the corrected scheduled transfer start time.

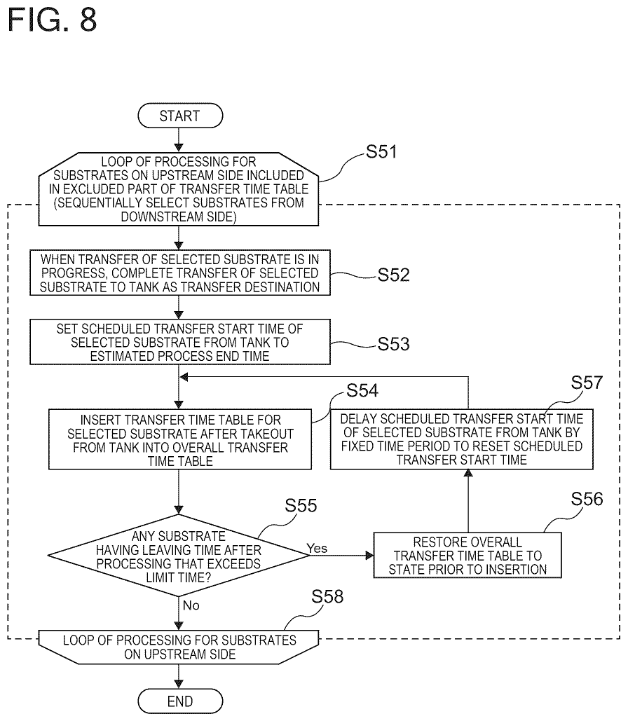

At step S35, the processing flow reinserts the second part of the transfer schedule for the non-transferred portion of the substrate(s) on the upstream side that are affected by the transfer of the object substrate, into the overall transfer schedule (as shown in FIG. 9D) by a processing flow described later with reference to FIG. 8.

At this step, the second part of the transfer schedule for the substrate on the upstream side after takeout from the tank/module is re-embedded between transfer schedules for other substrates in the overall transfer schedule, in accordance with the estimated process end time (S18) of the object substrate in the plating tank 112a or in accordance with the time determined by adding a predetermined time period to the actual process end time (S20) of the object substrate in the plating tank 112a.

More specifically, as described later with reference to FIG. 8, the processing flow corrects the scheduled transfer start time of the substrate on the upstream side from the tank/module to the estimated process end time (S18) or to the time determined by adding a predetermined time period to the actual process end time (S20), and reinserts the second part of the transfer schedule for the substrate on the upstream side after takeout from the tank/module, into the overall transfer schedule, while adjusting the overall transfer schedule (including the part reinserted previously) based on the corrected scheduled transfer start time.

At step S36, the processing flow performs rescheduling of the third part of the transfer schedule for the subsequent unprocessed substrates, with respect to the overall transfer schedule after reinsertion of the first part at step S34 and reinsertion of the second part at step S35 (as shown in FIG. 9D), and reinserts the third part of the transfer schedule for the subsequent unprocessed substrates, into the overall transfer schedule (as shown in FIG. 9E) by a process similar to the process of generating a transfer schedule for a new job. The process of reinserting the third part of the transfer schedule for the subsequent unprocessed substrates into the overall transfer schedule is equivalent to a process of generating a transfer schedule for substrates that have not yet been taken out from the cassette(s) and is accordingly performed in a similar manner to the process of generating a transfer schedule for a new job (step S13 shown in FIG. 5).

FIG. 7 is a flowchart showing a process of reinserting the first part of the transfer schedule for the object substrate after takeout from the plating tank, into the overall transfer schedule (step S34).

At step S41, the processing flow sets the scheduled transfer start time of the object substrate from the plating tank 112a to the estimated process end time (S18) or to the time determined by adding a predetermined time period to the actual process end time (S20). The predetermined time is set in advance by taking into account a time period required for adjustment of the transfer schedule.

At step S42, the processing flow inserts the first part of the transfer schedule for the object substrate after takeout from the plating tank into the overall transfer schedule (as shown in FIG. 9C), while adjusting the overall transfer schedule (as shown in FIG. 9B) in accordance with/based on the corrected scheduled transfer start time of the object substrate in the plating tank. The expression of “after takeout from the plating tank” herein denotes after a start of transfer from the plating tank.

At step S43, the processing flow determines whether there is any other substrate (any other substrate in the overall transfer schedule: as shown in FIG. 9B) having a leaving time after processing (a time period for which the substrate after processing is soaked in the processing solution before being unloaded) which exceeds a limit value.

When it is determined that there is no other substrate having the leaving time after processing which exceeds the limit value, the processing flow completes the insertion of the first part of the transfer schedule (for the object substrate after takeout from the plating tank) into the overall transfer schedule (as shown in FIG. 9C). Accordingly, the processing flow (of step S34) is terminated.

When it is determined that there is any other substrate having the leaving time after processing which exceeds the limit value, on the other hand, the processing flow proceeds to step S44.

The processing flow restores the overall transfer schedule to the state prior to the insertion of the first part of the transfer schedule for the object substrate after takeout from the plating tank (the state prior to the processing of step S42: as shown in FIG. 9B) at step S44 and then proceeds to step S45.

The processing flow further delays the scheduled transfer start time of the object substrate by a fixed time period to reset the scheduled transfer start time of the object substrate at step S45 and then returns to step S42 to repeat the processing of and after step S42. The processing flow accordingly repeats the process of returning the overall transfer schedule to the state prior to the insertion of the first part (step S44), further delaying the scheduled transfer start time by the fixed time period (step S45), and inserting the first part (step S42) until it is determined at step S43 that there is no other substrate having the leaving time after processing which exceeds the limit value. The fixed time period may be a time period set in advance.

When it is determined that there is no other substrate having the leaving time after processing which exceeds the limit value at step S43, the processing flow completes the insertion of the first part of the transfer schedule (for the object substrate after takeout from the plating tank) into the overall transfer schedule (as shown in FIG. 9C). Accordingly, the processing flow (of step S34) is terminated.

FIG. 8 is a flowchart showing a process of reinserting the second part of the transfer schedule for the non-transferred portion of the substrate(s) on the upstream side that are affected by transfer of the object substrate, into the overall transfer schedule (step S35). When there are a plurality of substrates on the upstream side that are affected by transfer of the object substrate, the processing of steps S52 to S55 (S57) is performed sequentially from a substrate on the most downstream side among the plurality of substrates on the upstream side.

At step S51, the processing flow selects a substrate on the most downstream side that has not yet been subjected to the processing of and after step S52, among the substrate(s) on the upstream side that are affected by the transfer of the object substrate.

When the transfer of the substrate selected at step S51 is in progress, the processing flow first completes the transfer of the selected substrate to a processing tank as a transfer destination at step S52.

At step S53, the processing flow sets a scheduled transfer start time of the substrate selected at step S51 from the current processing tank to an estimated process end time of the object substrate (S17) or to a time determined by adding a predetermined time period to an actual process end time of the object substrate (S20). Accordingly, the scheduled transfer start time when the substrate selected at step S51 is to be taken out from the current processing tank is updated to the estimated process end time of the object substrate (S17) or to the time determined by adding the predetermined time period to the actual process end time of the object substrate (S20).

At step S54, the processing flow inserts a transfer schedule for the substrate selected at step S51 after takeout from the current processing tank (a portion of the second part corresponding to the substrate selected at step S51), into the overall transfer schedule (as shown in FIG. 9D), while adjusting the overall transfer schedule in accordance with/based on the corrected scheduled transfer start time of the substrate selected at step S51 in the current processing tank.

At step S55, the processing flow determines whether there is any other substrate (any other substrate in the overall transfer schedule) having a leaving time after processing which exceeds a limit value. When it is determined that there is no other substrate having the leaving time after processing which exceeds the limit value, the processing flow proceeds to step S58. When it is determined that there is any other substrate having the leaving time after processing which exceeds the limit value, on the other hand, the processing flow proceeds to step S56.

The processing flow restores the overall transfer schedule to the state prior to insertion of the transfer schedule for the substrate selected at step S51 (the portion of the second part corresponding to the substrate selected at step S51) (to the state prior to the processing of step S54) at step S56 and then proceeds to step S57.

The processing flow further delays the scheduled transfer start time of the substrate selected at step S51 by a fixed time period to reset the scheduled transfer start time of the selected substrate at step S57 and then returns to step S54 to repeat the processing of and after step S54. The processing flow accordingly repeats the process of returning the overall transfer schedule to the state prior to the insertion at step S54 (step S56), further delaying the scheduled transfer start time by the fixed time period (step S57), and reinserting the portion of the second part corresponding to the selected substrate (step S54) until it is determined at step S55 that there is no other substrate having the leaving time after processing which exceeds the limit value. The fixed time period may be a time period set in advance.

When it is determined at step S55 that there is no other substrate having the leaving time after processing which exceeds the limit value, the processing flow proceeds to step S58.

At step S58, the processing flow determines whether there is or there are any remaining substrate(s) that have not yet been subjected to the processing of and after step S52, among the substrates on the upstream side that are affected by the transfer of the object substrate (the substrates included in the second part of the transfer schedule). When there is or there are any remaining substrates, the processing flow selects a substrate on the most downstream side among the remaining substrates at step S51 and then executes the processing of and after step S52. When there is no remaining substrate, on the other hand, the processing flow completes the insertion of the second part of the transfer schedule for the non-transferred portion of the substrates on the upstream side that are affected by the transfer of the object substrate, into the overall transfer schedule (as shown in FIG. 9D). Accordingly, the processing flow (of step S35 in FIG. 6) is terminated.

After termination of the processing of step S35 in FIG. 6, at step S36, the processing flow performs rescheduling of the third part of the transfer schedule for the subsequent unprocessed substrates, with respect to the overall transfer schedule after reinsertion of the first part and the second part (as shown in FIG. 9D), and reinserts the third part of the transfer schedule for the subsequent unprocessed substrates, into the overall transfer schedule (as shown in FIG. 9E) by the process similar to the process of generating the transfer schedule for a new job, as described above. This completes the adjustment of the transfer schedule, i.e., generation of the adjusted transfer schedule (step S19 or step S21).

### Exemplified Calculation Methods of Margin Time

The following describes exemplified calculation methods of the margin time at step S12 in FIG. 5. Statistical values based on past plating data or a learning network may be used for calculation of the margin time, which is to be added to the plating process time (the time set in the recipe) shown in FIG. 4A and FIG. 4B.

### (1) Example of Method of Calculating Margin Time by Using Learning Network

The margin time may be calculated by a learning network (machine learning). For example, a learnt network that has been machine-learnt/trained with past plating data as teacher data may be used to calculate the margin time. Input parameters and output parameters of the learning network may be set as follows:
(inputs) plating process time set in the recipe, plating current value set in the recipe, film thickness target value, chemical component, chemical temperature, circulation flow rate, paddle speed, and substrate information (aperture ratio, area)
(outputs) margin time (=historical time required for plating−plating process time set in the recipe) (herein the historical time required for plating=actually measured plating process time).

In the case of plating a substrate, the method provides input values suitable for a substrate to be plated, as the inputs of the learning network (learnt network) and calculates the margin time.

The inputs of the learning network may include parameters other than those given above, may exclude part of the above parameters or may be a combination of parameters other than those given above.

The margin time is not necessarily a positive value. A negative value of the margin time is set when the plating process is terminated in a shorter time period than the plating process time set in the recipe. The method sets the margin time, such that the actual plating process time does not exceed the plating process time set in the recipe+margin time with regard to most substrates, irrespective of the positive/negative value of the margin time. The same applies to the following examples.

Only data having the actual process end time that is beyond (or that is ahead of) the process end time set in the recipe may be used as the past plating data. The same applies to the examples of (2) and (3) described below.

### (2) Example 1 of Method of Calculating Margin Time from Statistical Value Based on Plating Data

This method calculates a statistical value of time required for plating and calculates the margin time based on the statistical value of the time required for plating by using Mathematical Expression 1 to Mathematical Expression 3 given below. The left side of Mathematical Expression 1 is an average value of time required for plating [min] (also shown as <Tm>). A factor in Σ on the right side of Mathematical Expression 1 is a measurement value of time required for plating of the substrates [min] (also shown as Tm(n)). In these mathematical expressions, n denotes a data number and N denotes a total number of data. In Mathematical Expression 2, σ² denotes a dispersion in a distribution of the measurement values of time required for plating of the substrates. In Mathematical Expression 3, t_{margin} denotes a margin time [min], t_{recipe} denotes a plating process time [min] set in the recipe, σ denotes a standard deviation (square root of the dispersion), and a denotes a multiple of σ. The addition of ασ in Mathematical Expression 3 is performed for the purpose of adjustment of the margin time in the positive (+) direction.

$$\overline{{T}_{m}} = \frac{1}{N} {\sum }_{n = 1}^{N} {T}_{m}^{( n )} \qquad [ Math . 1 ]$$

$${σ}^{2} = \frac{1}{N - 1} {{\sum }^{N}}_{n = 1} {( {T}_{m}^{( n )} - \overline{{T}_{m}} )}^{2} \qquad [ Math . 2 ]$$

$${t}_{margin} = ( \overline{{T}_{m}} + ασ ) - {t}_{recipe} \qquad [ Math . 3 ]$$

Mathematical Expression 3 shows calculation of the margin time that enables the plating process to be completed within the plating process time (set in the recipe) t_{recipe}+margin time t_{margin} with regard to substrates in a range of α-fold value of a standard deviation σ among the substrates included in the past plating data. For example, when α=3, this method calculates the margin time that enables the plating process to be completed within the plating process time (set in the recipe)+margin time with regard to substrates in a range of 3σ, i.e., 3-fold value of the standard deviation σ. When a distribution of the measurement values of plating time is a normal distribution, the number of the substrates in the range of 3σ is 99.7% of all the substrates. Accordingly, this method calculates the margin time that enables the plating process to be completed within the plating process time (set in the recipe)+margin time with regard to 99.7% of the substrates.

The above calculation formulae are on the premise that the target film thickness and the plating rate for the substrates are fixed values. The time required for plating is varied depending on the plating rate and the target film thickness. This method accordingly collects measurement values of an average time required for plating [min] (<Tm>) and calculates the margin time, with regard to each combination of the target film thickness and the plating rate.

The plating rate may vary non-linearly according to the plating film thickness and the plating conditions such as the current density. In such cases, in terms of the accuracy, the method using the learning network is preferable to the calculation of the margin time by using the theoretical formulae as described above.

### (3) Example 2 of Method of Calculating Margin Time from Statistical Value Based on Plating Data

As shown in Mathematical Expression 4 to Mathematical Expression 7 given below, this method calculates the plating rate from the measurement value of the plating film thickness and the time required for plating (the time required for plating process), calculates a statistical value of the plating rate, and then calculates the margin time.

The left side of Mathematical Expression 4 is a measured value of plating rate [μm/min] (also shown as Am(n)). The numerator on the right side of mathematical Expression 4 is a measured value of film thickness [μm] (also shown as Xm(n)). The denominator on the right side of Mathematical Expression 4 is a measured value of plating process time [min] (also shown as Tm(n)). The left side of Mathematical Expression 5 is an average value of measurement values of plating rate [um/min] (also shown as <Am>). In these mathematical expressions, n denotes a data number and N denotes a total number of data. In Mathematical Expression 6, σ² denotes a dispersion in a distribution of the measurement values of plating rate of the substrates. In Mathematical Expression 7, t_{margin} denotes a margin time [min], X_{trarget} denotes a target film thickness [μm], t_{recipe} denotes a plating process time [min] set in the recipe, σ denotes a standard deviation (square root of the dispersion), and α denotes a multiple of σ. The subtraction of ασ in Mathematical Expression 7 is performed for the purpose of adjustment of the margin time in the positive (+) direction.

As described above with regard to Mathematical Expression 3, Mathematical Expression 7 shows calculation of the margin time that enables the plating process to be completed within the plating process time (set in the recipe) t_{recipe}+margin time t_{margin} with regard to substrates in a range of the α-fold value of the standard deviation σ among the substrates included in the past plating data. For example, when α=3, this method calculates the margin time that enables the plating process to be completed within the plating process time (set in the recipe)+margin time with regard to substrates in a range of 3σ, i.e., 3-fold value of the standard deviation σ. When a distribution of the measurement value of plating rate is a normal distribution, the number of the substrates in the range of 3σ is 99.7% of all the substrates. Accordingly, this method calculates the margin time that enables the plating process to be completed within the plating process time (set in the recipe)+margin time with regard to 99.7% of the substrates.

$${A}_{m}^{( n )} = \frac{{X}_{m}^{( n )}}{{T}_{m}^{( n )}} \qquad [ Math . 4 ]$$

$$\overline{{A}_{m}} = \frac{1}{N} {\sum }_{n = 1}^{N} {A}_{m}^{( n )} \qquad [ Math . 5 ]$$

$${σ}^{2} = \frac{1}{N - 1} {\sum }_{n = 1}^{N} {( {A}_{m}^{( n )} - \overline{{A}_{m}} )}^{2} \qquad [ Math . 6 ]$$

$${t}_{margin} = \frac{{X}_{target}}{( \overline{{A}_{m}} - α σ )} - {t}_{recipe} \qquad [ Math . 7 ]$$

The calculation formulae given above are on the premise that the current density applied on substrates is a fixed value. The plating rate varies depending on the current density. This method accordingly collects measurement values of the plating rate [μm/min] (Am(n)) with regard to each current density and calculates the margin time.

In some cases, a theoretical plating deposition value (γ) may not be a fixed value but may vary (may become non-linear), depending on the current density and other plating conditions. In such cases, in terms of the accuracy, the method using the learning network is preferable to the calculation of the margin time by using the theoretical formulae as described above.

### Exemplified Calculation Methods of Estimated Plating End Time

### (1) Example of Method of Calculating Estimated Plating End Time by Using Learning Network

The estimated plating end time may be calculated by a learning network (machine learning). For example, a learnt network that has been machine-learnt/trained with past plating data as teacher data may be used to calculate the estimated plating end time (S17 in FIG. 5). Input parameters and output parameters of the learning network may be set as follows:
(inputs) plating time elapsed/measured current value, target value/present value of film thickness, chemical component, chemical temperature, circulation flow rate, paddle speed, and substrate information
(outputs) expected remaining plating time

The estimated plating end time may be calculated as present time+expected remaining plating time=estimated plating end time. The present time may be calculated as plating start time+plating time elapsed. In the case where a rinse process is performed in a plating tank, the estimated process end time in the plating tank may be calculated by adding a rinse process time to the estimated plating end time.

The inputs of the learning network may include parameters other than those given above, may exclude part of the above parameters or may be a combination of parameters other than those given above.

### (2) Example of Method of Calculating Estimated Plating End Time by Rule-Based Calculation Formula

A procedure of calculating the estimated plating end time (S17 in FIG. 5) by simple calculation calculates a remaining film thickness from a difference between a target film thickness and a measurement value of film thickness, calculates an expected remaining plating time from a statistical value of plating rate (for example, an average value of measurement values of plating rate), and adds the expected remaining plating time to the present time (plating start time+plating time elapsed), so as to obtain the estimated plating end time (as shown by Equation 1 given below).

Estimated Plating End Time=(Target Film Thickness−Measurement Value of Film Thickness)/(Average Value of Measurement Values of Plating Rate)+(Plating Start Time+Plating Time Elapsed) (Equation 1)

### Other Embodiments

(1) The adjustment scheduling of the transfer schedule described above has a purpose of reinserting the first part of the transfer schedule for the object substrate after takeout from the plating tank, the second part of the transfer schedule for the non-transferred portion for the substrates on the upstream side affected by the transfer of the object substrate, and the third part of the transfer schedule for the subsequent unprocessed substrates, between transfers (transfer schedule) for other substrates. Under the conditions satisfying this purpose, a graph network method, a simulation method, machine learning or any other scheduling method may be employed.

(2) In the case where the estimated plating end time is behind the plating end time set in the recipe (+margin time), the rinse time may be shortened in an adjustable range that does not affect the rinse performance. In the case where the estimated plating end time is ahead of the plating end time set in the recipe (+margin time), on the contrary, the rinse time may be elongated in an adjustable range that does not affect the rinse performance.

(3) In the case where the estimated process end time of the plating process time (+margin time)+rinse time does not go past the scheduled transfer start time, there is no need to perform adjustment of the transfer schedule. The adjustment of the transfer schedule may, however, be performed even in this case.

(4) Even in the case where the actual processing time is elongated with regard to most substrates by a first substrate loading scheduling, it is not necessary to set the margin time. Even in this case, the configuration of the embodiment may perform measurement of the film thickness during the plating process, calculation of the estimated process end time, and adjustment scheduling of the transfer schedule. The configuration of the above embodiment may thus omit the setting of the margin time and may perform adjustment scheduling of the transfer schedule based on the measurement value of film thickness.

(5) The margin time is set in order to enable the plating process to be terminated within the plating process time (the time set in the recipe)+margin time with regard to most substrates. Adjustment scheduling of the transfer schedule during operation of the substrate processing apparatus may thus be omitted as needed basis.

(6) The configuration of the above embodiment performs adjustment of the transfer schedule in the case where the estimated process end time (or the actual process end time) is behind (beyond) the scheduled transfer start time. A modified configuration may set the scheduled transfer start time to the estimated process end time (or the actual process end time) and perform adjustment of the transfer schedule, in the case where the estimated process end time (or the actual process end time) is ahead of the scheduled transfer start time.

At least the following technical concepts are provided from the description of the above embodiments.

[1] According to one aspect, there is provided an apparatus for processing a substrate, comprising: a plurality of processing tanks, each being configured to perform processing of a substrate; a transfer machine configured to transfer the substrate; and a controller configured to generate a transfer schedule, which causes the substrate to be transferred between the plurality of processing tanks and to be processed, and configured to control the transfer of the substrate by the transfer machine and control the processing of the substrate in each of the plurality of processing tanks, based on the transfer schedule, wherein the plurality of processing tanks include a first processing tank configured such that one or a plurality of processes including a first process are performed for the substrate therein, and the controller adds a positive or negative margin time to a processing time of the first process that is set in a recipe to generate the transfer schedule, wherein the margin time is calculated by a learning network or a statistical calculation method using actually measured processing times obtained by actually performing the first process with regard to a plurality of substrates in the first processing tank. The actually measured processing time denotes a measured time taken to perform the first process.

The configuration of this aspect adds the margin time, which is calculated from past processed data by the learning network or by the statistical calculation method, to the processing time (the time set in the recipe) of the first process and thereby increases the possibility that the first process is completed in a range of the processing time (the time set in the recipe) of the first process+margin time, even in the case where the process end time of the first process is varied. This configuration reduces the possibility that the actual process end time of the first process is behind the process end time set in the recipe and that other substrates cannot keep a limit value of a leaving time after processing, due to the disturbance of transfer.

Processed data used for calculation of a subsequent margin time may be updated by adding an actually measured processing time in the case where the first process is performed with setting of the margin time, to the processed data. In this manner, increasing the frequency of the first process enhances the accuracy of the margin time.

The negative margin time is given in the case where the past processed data include data with regard to a lot of substrates having the actually measured processing time of the first process that is shorter than the processing time set in the recipe.

[2] According to one aspect, in the apparatus for processing the substrate, the margin time may be calculated, such that an actually measured processing time of a substrate in a range of a 3σ value that is a threefold value of a standard deviation σ, among the plurality of substrates, does not exceed a time determined by adding the margin time to the processing time of the first process that is set in the recipe, based on statistical calculation of measurement values including the actually measured processing times obtained by actually performing the first process with regard to the plurality of substrates in the first processing tank.

The measurement values may include measured values of various physical quantities at the time of performing the first process (in the case of a plating process, for example, a plating process time, a plating film thickness and a plating rate).

The configuration of this aspect enables the first process to be completed in a range of the processing time (the time set in the recipe) of the first process+margin time at a high accuracy or more specifically, with regard to most substrates in the range of 3σ value (99.7% in the normal distribution).

[3] According to one aspect, in the apparatus for processing the substrate, the first processing tank may be provided with a sensor configured to detect a degree of progress of the first process, and the controller may estimate an estimated process end time, which is a time point when all the one or the plurality of processes performed in the first processing tank are terminated, from a detection value obtained from the sensor, and when it is determined that the estimated process end time is behind a scheduled transfer start time set in the transfer schedule, may correct the scheduled transfer start time to the estimated process end time and may adjust the transfer schedule.

The configuration of this aspect provides the margin time to increase the possibility that the first process is completed in a range of the processing time (the time set in the recipe)+margin time and furthermore monitors the estimated process end time in the first processing tank. When the estimated process end time is behind the scheduled transfer start time, the configuration of this aspect corrects the scheduled transfer start time to the estimated process end time and adjusts the transfer schedule. This configuration further reduces the possibility that other substrates cannot keep the limit value of the leaving time after processing, due to the disturbance of transfer caused by a variation in the estimated process end time (or actual process end time).

If the configuration of performing adjustment of the transfer schedule in the case where the estimated process end time is behind the scheduled transfer start time is employed, the load of the adjustment of the transfer schedule can be minimized. The adjustment of the transfer schedule may, however, be performed even in the case where the estimated process end time is ahead of the scheduled transfer end time.

[4] According to one aspect, in the apparatus for processing the substrate, the controller may once exclude a first part of the transfer schedule corresponding to a portion for a certain substrate after unloading of the certain substrate from the first processing tank, wherein the certain substrate is determined to have the estimated process end time that is behind the scheduled transfer start time, a second part of the transfer schedule corresponding to a non-transferred portion for one or a plurality of substrates on an upstream side of the certain substrate/first processing tank that are affected by transfer of the certain substrate, and a third part of the transfer schedule for one or a plurality of subsequent unprocessed substrates that are still placed in a substrate container, from the transfer schedule; may correct the scheduled transfer start time to the estimated process end time; and may reinsert the first part, the second part and the third part into the transfer schedule, in accordance with the corrected scheduled transfer start time, so as to adjust the transfer schedule.

The configuration of this aspect once excludes only the parts of the transfer schedule that require adjustment, from the transfer schedule and then re-embeds the excluded parts into the transfer schedule, in accordance with the scheduled transfer start time that is corrected to the estimated process end time. This configuration enables the transfer schedule to be adjusted by a minimum necessary process and generates the adjusted transfer schedule.

[5] According to one aspect, in the apparatus for processing the substrate, in a case where, after an actual process end time which is a time point when all the one or plurality of processes in the first processing tank were terminated, it is determined that the actual process end time is beyond the scheduled transfer start time, the controller may correct the scheduled transfer start time to a time determined by adding a predetermined time period to the actual process end time and may adjust the transfer schedule.

The configuration of this aspect causes the transfer schedule to be adjusted, even when it is determined, after termination of the processing in the first processing tank, that the actual process end time is beyond the scheduled transfer start time. This configuration further reduces the possibility that other substrates cannot keep the limit value of the leaving time after processing, due to the disturbance of the transfer in relation to the first process.

[6] According to one aspect, in the apparatus for processing the substrate, the controller may once exclude a first part of the transfer schedule corresponding to a portion for a certain substrate after unloading of the certain substrate from the first processing tank, wherein the certain substrate is determined to have the actual process end time that is beyond the scheduled transfer start time, a second part of the transfer schedule corresponding to a non-transferred portion for one or a plurality of substrates on an upstream side of the certain substrate/first processing tank that are affected by transfer of the certain substrate, and a third part of the transfer schedule for one or a plurality of subsequent unprocessed substrates that are still placed in a substrate container, from the transfer schedule; may correct the scheduled transfer start time to the time determined by adding the predetermined time period to the actual process end time; and may reinsert the first part, the second part and the third part into the transfer schedule, in accordance with the corrected scheduled transfer start time, so as to adjust the transfer schedule.

The configuration of this aspect once excludes only the parts of the transfer schedule that require adjustment, from the transfer schedule and then re-embeds the excluded parts into the transfer schedule, in accordance with the scheduled transfer start time that is corrected to the “time determined by adding the predetermined time period to the actual process end time”. This configuration enables the transfer schedule to be adjusted by a minimum necessary process and generates the adjusted transfer schedule.

[7] According to one aspect, in the apparatus for processing the substrate, the controller may generate the transfer schedule by using a graph network-type scheduler, a simulation-type scheduler or a machine learning-type scheduler.

The configuration of this aspect enables the transfer schedule to be generated or adjusted by using a variety of schedulers.

[8] According to one aspect, in the apparatus for processing the substrate, the first process may be a plating process, and the one or plurality of processes may include a plating process alone or a plating process and a rinse process.

The configuration of this aspect reduces the possibility that other substrates cannot keep the limit value of the leaving time after processing, due to the disturbance of transfer caused by a variation in plating process time.

[9] According to one aspect, there is provided an apparatus for processing a substrate, comprising: a plurality of processing tanks, each being configured to perform processing of a substrate; a transfer machine configured to transfer the substrate; and a controller configured to generate a transfer schedule, which causes the substrate to be transferred between the plurality of processing tanks and to be processed, and configured to control the transfer of the substrate by the transfer machine and control the processing of the substrate in each of the plurality of processing tanks, based on the transfer schedule, wherein the plurality of processing tanks include a first processing tank, which is configured such that one or a plurality of processes including a first process are performed for the substrate therein and which is provided with a sensor configured to detect a degree of progress of the first process, and the controller estimates an estimated process end time, which is a time point when all the one or the plurality of processes performed in the first processing tank are terminated, from a detection value obtained from the sensor, and when it is determined that the estimated process end time is behind a scheduled transfer start time set in the transfer schedule, corrects the scheduled transfer start time to the estimated process end time and adjusts the transfer schedule in accordance with the corrected scheduled transfer start time.

The configuration of this aspect estimates the estimated process end time, based on the detection value of the sensor in the course of processing of the substrate and monitors the estimated process end time in the first processing tank. When the estimated process end time is behind the scheduled transfer start time, the configuration of this aspect corrects the scheduled transfer start time to the estimated process end time and adjusts the transfer schedule. This configuration reduces the possibility that other substrates cannot keep the limit value of the leaving time after processing, due to the disturbance of transfer caused by a variation in the estimated process end time (or actual process end time).

If the configuration of performing adjustment of the transfer schedule in the case where the estimated process end time is behind the scheduled transfer start time is employed, the load of the adjustment of the transfer schedule can be minimized. The adjustment of the transfer schedule may, however, be performed even in the case where the estimated process end time is ahead of the scheduled transfer end time.

[10] According to one aspect, in the apparatus for processing the substrate, the controller may once exclude a first part of the transfer schedule corresponding to a portion for a certain substrate after unloading of the certain substrate from the first processing tank, wherein the certain substrate is determined to have the estimated process end time that is behind the scheduled transfer start time, a second part of the transfer schedule corresponding to a non-transferred portion for one or a plurality of substrates on an upstream side of the certain substrate/first processing tank that are affected by transfer of the certain substrate, and a third part of the transfer schedule for one or a plurality of subsequent unprocessed substrates that are still placed in a substrate container, from the transfer schedule; may correct the scheduled transfer start time to the estimated process end time; and may reinsert the first part, the second part and the third part into the transfer schedule, in accordance with the corrected scheduled transfer start time, so as to adjust the transfer schedule.

The configuration of this aspect once excludes only the parts of the transfer schedule that require adjustment, from the transfer schedule and then re-embeds the excluded parts into the transfer schedule, in accordance with the scheduled transfer start time that is corrected to the estimated process end time. This configuration enables the transfer schedule to be adjusted by a minimum necessary process and generates the adjusted transfer schedule.

[11] According to one aspect, in the apparatus for processing the substrate, in a case where, after an actual process end time which is a time point when all the one or plurality of processes in the first processing tank were terminated, it is determined that the actual process end time is beyond the scheduled transfer start time, the controller may correct the scheduled transfer start time to a time determined by adding a predetermined time period to the actual process end time and may adjust the transfer schedule.

The configuration of this aspect causes the transfer schedule to be adjusted, even when it is determined, after termination of the processing in the first processing tank, that the actual process end time is beyond the scheduled transfer start time. This configuration further reduces the possibility that other substrates cannot keep the limit value of the leaving time after processing, due to the disturbance of the transfer in relation to the first process.

[12] According to one aspect, in the apparatus for processing the substrate, the controller may once exclude a first part of the transfer schedule corresponding to a portion for a certain substrate after unloading of the certain substrate from the first processing tank, wherein the certain substrate is determined to have the actual process end time that is beyond the scheduled transfer start time, a second part of the transfer schedule corresponding to a non-transferred portion for one or a plurality of substrates on an upstream side of the certain substrate/first processing tank that are affected by transfer of the certain substrate, and a third part of the transfer schedule for one or a plurality of subsequent unprocessed substrates that are still placed in a substrate container, from the transfer schedule; may correct the scheduled transfer start time to the time determined by adding the predetermined time period to the actual process end time; and may reinsert the first part, the second part and the third part into the transfer schedule, in accordance with the corrected scheduled transfer start time, so as to adjust the transfer schedule.

The configuration of this aspect once excludes only the parts of the transfer schedule that require adjustment, from the transfer schedule and then re-embeds the excluded parts into the transfer schedule, in accordance with the scheduled transfer start time that is corrected to the “time determined by adding the predetermined time period to the actual process end time”. This configuration enables the transfer schedule to be adjusted by a minimum necessary process and generates the adjusted transfer schedule.

[13] According to one aspect, in the apparatus for processing the substrate, the controller may calculate the estimated process end time by a rule-based calculation formula or a learnt network using the detection value of the sensor.

The configuration of this aspect enables the estimated process end time to be readily calculated by the rule-based calculation formula using the detection value of the sensor, parameters set in the recipe and the like or enables the estimated process end time of high accuracy to be calculated by using the learnt network.

[14] According to one aspect, in the apparatus for processing the substrate, the controller may generate and adjust the transfer schedule by using a graph network-type scheduler, a simulation-type scheduler or a machine learning-type scheduler.

The configuration of this aspect enables the transfer schedule to be generated or adjusted by using a variety of schedulers.

[15] According to one aspect, in the apparatus for processing the substrate, the first process may be a plating process, and the one or plurality of processes may include a plating process alone or a plating process and a rinse process.

The configuration of this aspect reduces the possibility that other substrates cannot keep the limit value of the leaving time after processing, due to the disturbance of transfer caused by a variation in plating process time.

[16] According to one aspect, there is provided a method of controlling an apparatus for processing a substrate, which comprises a plurality of processing tanks, each being configured to perform processing of a substrate; and a transfer machine configured to transfer the substrate, wherein the plurality of processing tanks include a first processing tank configured such that one or a plurality of processes including a first process are performed for the substrate therein. The method of controlling the apparatus for processing the substrate comprises: generating a transfer schedule, which causes the substrate to be transferred between the plurality of processing tanks and to be processed, and controlling the transfer of the substrate by the transfer machine and controlling the processing of the substrate in each of the plurality of processing tanks, based on the transfer schedule; and adding a positive or negative margin time to a processing time of the first process that is set in a recipe to generate the transfer schedule, wherein the margin time is calculated by a learning network or a statistical calculation method using actually measured processing times obtained by actually performing the first process with regard to a plurality of substrates in the first processing tank.

According to one aspect, there is provided a storage medium configured to store therein a program that causes a computer to perform a method of controlling an apparatus for processing a substrate, which comprises a plurality of processing tanks, each being configured to perform processing of a substrate; and a transfer machine configured to transfer the substrate, wherein the plurality of processing tanks include a first processing tank configured such that one or a plurality of processes including a first process are performed for the substrate therein. The program causes the computer to perform: generating a transfer schedule, which causes the substrate to be transferred between the plurality of processing tanks and to be processed, and controlling the transfer of the substrate by the transfer machine and controlling the processing of the substrate in each of the plurality of processing tanks, based on the transfer schedule; and adding a positive or negative margin time to a processing time of the first process that is set in a recipe to generate the transfer schedule, wherein the margin time is calculated by a learning network or a statistical calculation method using actually measured processing times obtained by actually performing the first process with regard to a plurality of substrates in the first processing tank.

[18] According to one aspect, there is provided a method of controlling an apparatus for processing a substrate, which comprises a plurality of processing tanks, each being configured to perform processing of a substrate; and a transfer machine configured to transfer the substrate, wherein the plurality of processing tanks include a first processing tank, which is configured such that one or a plurality of processes including a first process are performed for the substrate therein and which is provided with a sensor configured to detect a degree of progress of the first process. The method of controlling the apparatus for processing the substrate comprises: generating a transfer schedule, which causes the substrate to be transferred between the plurality of processing tanks and to be processed, and controlling the transfer of the substrate by the transfer machine and controlling the processing of the substrate in each of the plurality of processing tanks, based on the transfer schedule; and estimating an estimated process end time, which is a time point when all the one or the plurality of processes performed in the first processing tank are terminated, from a detection value obtained from the sensor, and when it is determined that the estimated process end time is behind a scheduled transfer start time set in the transfer schedule, correcting the scheduled transfer start time to the estimated process end time and adjusting the transfer schedule.

According to one aspect, there is provided a storage medium configured to store therein a program that causes a computer to perform a method of controlling an apparatus for processing a substrate, which comprises a plurality of processing tanks, each being configured to perform processing of a substrate; and a transfer machine configured to transfer the substrate, wherein the plurality of processing tanks include a first processing tank, which is configured such that one or a plurality of processes including a first process are performed for the substrate therein and which is provided with a sensor configured to detect a degree of progress of the first process. The program causes the computer to perform: generating a transfer schedule, which causes the substrate to be transferred between the plurality of processing tanks and to be processed, and controlling the transfer of the substrate by the transfer machine and controlling the processing of the substrate in each of the plurality of processing tanks, based on the transfer schedule; and estimating an estimated process end time, which is a time point when all the one or the plurality of processes performed in the first processing tank are terminated, from a detection value obtained from the sensor, and when it is determined that the estimated process end time is behind a scheduled transfer start time set in the transfer schedule, correcting the scheduled transfer start time to the estimated process end time and adjusting the transfer schedule.

Although the embodiments of the present invention have been described based on some examples, the embodiments of the invention described above are presented to facilitate understanding of the present invent ion, and do not limit the present invention. The present invention can be altered and improved without departing from the subject matter of the present invention, and it is needless to say that the present invention includes equivalents thereof. In addition, it is possible to arbitrarily combine or omit respective constituent elements described in the claims and the specification in a range where at least a part of the above-mentioned problem can be solved or a range where at least a part of the effect is exhibited.

The present application claims priority to Japanese patent application No. 2023-215584 filed on Dec. 21, 2023. The entire disclosure of Japanese patent application No. 2023-215584 filed on Dec. 21, 2023, including the specification, claims, drawings and abstract is incorporated herein by reference in its entirety.

The entire disclosures of Japanese Unexamined Patent Publication No. 2022-181368 (PTL 1), Japanese Unexamined Patent Publication No. 2011-018738 (PLT 2), and Japanese Unexamined Patent Publication No. 2021-36582 (PLT 3) including the specifications, claims, drawings and abstracts are incorporated herein by reference in its entirety.

### REFERENCE SIGNS LIST

100 substrate processing apparatus
101A loading/unloading station
101B processing station
102 cassette table
103 transfer robot
104 aligner
105 substrate attachment/detachment station
105a substrate attachment/detachment device
106 spin rinse dryer
107 stocker
108 pre-wet module
109 pre-soak module
110a pre-soak rinse module
110b rinse module
111 blow module
112 plating process module
112a plating tank (cell)
113 substrate holder transfer device
114 transfer machine (transporter)
115 transfer machine (transporter)
116 rail
120 device computer
120A CPU
120B memory
120C operation screen application
120D transfer scheduler
121 device controller
130 operation device
1201 transfer schedule generator
1202 HMI part
1203 margin time calculator
1205 schedule adjustment determiner
1206 estimated process end time calculator
1207 plating film thickness measurement part

What is claimed is:

1. An apparatus for processing a substrate, comprising:
a plurality of processing tanks, each being configured to perform processing of a substrate;
a transfer machine configured to transfer the substrate; and
a controller configured to generate a transfer schedule, which causes the substrate to be transferred between the plurality of processing tanks and to be processed, and configured to control the transfer of the substrate by the transfer machine and control the processing of the substrate in each of the plurality of processing tanks, based on the transfer schedule, wherein
the plurality of processing tanks include a first processing tank configured such that one or a plurality of processes including a first process are performed for the substrate therein, and
the controller adds a positive or negative margin time to a processing time of the first process that is set in a recipe to generate the transfer schedule, wherein the margin time is calculated by a learning network or a statistical calculation method using actually measured processing times obtained by actually performing the first process with regard to a plurality of substrates in the first processing tank.

2. The apparatus for processing the substrate according to claim 1,
wherein the margin time is calculated, such that an actually measured processing time of a substrate in a range of a 3σ value that is a threefold value of a standard deviation σ, among the plurality of substrates, does not exceed a time determined by adding the margin time to the processing time of the first process that is set in the recipe, based on statistical calculation of measurement values including the actually measured processing times obtained by actually performing the first process with regard to the plurality of substrates in the first processing tank.

3. The apparatus for processing the substrate according to claim 1,
wherein the first processing tank is provided with a sensor configured to detect a degree of progress of the first process, and
the controller estimates an estimated process end time, which is a time point when all the one or the plurality of processes performed in the first processing tank are terminated, from a detection value obtained from the sensor, and when it is determined that the estimated process end time is behind a scheduled transfer start time set in the transfer schedule, corrects the scheduled transfer start time to the estimated process end time and adjusts the transfer schedule.

4. The apparatus for processing the substrate according to claim 3,
wherein the controller once excludes a first part of the transfer schedule corresponding to a portion for a certain substrate after unloading of the certain substrate from the first processing tank, wherein the certain substrate is determined to have the estimated process end time that is behind the scheduled transfer start time, a second part of the transfer schedule corresponding to a non-transferred portion for one or a plurality of substrates on an upstream side that are affected by transfer of the certain substrate, and a third part of the transfer schedule for one or a plurality of subsequent unprocessed substrates that are still placed in a substrate container, from the transfer schedule; corrects the scheduled transfer start time to the estimated process end time; and reinserts the first part, the second part and the third part into the transfer schedule, in accordance with the corrected scheduled transfer start time, so as to adjust the transfer schedule.

5. The apparatus for processing the substrate according to claim 3,
wherein in a case where, after an actual process end time which is a time point when all the one or plurality of processes in the first processing tank were terminated, it is determined that the actual process end time is beyond the scheduled transfer start time, the controller corrects the scheduled transfer start time to a time determined by adding a predetermined time period to the actual process end time and adjusts the transfer schedule.

6. The apparatus for processing the substrate according to claim 5,
wherein the controller once excludes a first part of the transfer schedule corresponding to a portion for a certain substrate after unloading of the certain substrate from the first processing tank, wherein the certain substrate is determined to have the actual process end time that is beyond the scheduled transfer start time, a second part of the transfer schedule corresponding to a non-transferred portion for one or a plurality of substrates on an upstream side that are affected by transfer of the certain substrate, and a third part of the transfer schedule for one or a plurality of subsequent unprocessed substrates that are still placed in a substrate container, from the transfer schedule; corrects the scheduled transfer start time to the time determined by adding the predetermined time period to the actual process end time; and reinserts the first part, the second part and the third part into the transfer schedule, in accordance with the corrected scheduled transfer start time, so as to adjust the transfer schedule.

7. The apparatus for processing the substrate according to claim 1,
wherein the controller generates the transfer schedule by using a graph network-type scheduler, a simulation-type scheduler or a machine learning-type scheduler.

8. The apparatus for processing the substrate according to claim 1,
wherein the first process is a plating process, and
the one or plurality of processes include a plating process alone or a plating process and a rinse process.

9. An apparatus for processing a substrate, comprising:
a plurality of processing tanks, each being configured to perform processing of a substrate;
a transfer machine configured to transfer the substrate; and
a controller configured to generate a transfer schedule, which causes the substrate to be transferred between the plurality of processing tanks and to be processed, and configured to control the transfer of the substrate by the transfer machine and control the processing of the substrate in each of the plurality of processing tanks, based on the transfer schedule, wherein
the plurality of processing tanks include a first processing tank, which is configured such that one or a plurality of processes including a first process are performed for the substrate therein and which is provided with a sensor configured to detect a degree of progress of the first process, and
the controller estimates an estimated process end time, which is a time point when all the one or the plurality of processes performed in the first processing tank are terminated, from a detection value obtained from the sensor, and when it is determined that the estimated process end time is behind a scheduled transfer start time set in the transfer schedule, corrects the scheduled transfer start time to the estimated process end time and adjusts the transfer schedule in accordance with the corrected scheduled transfer start time.

10. The apparatus for processing the substrate according to claim 9,
wherein the controller once excludes a first part of the transfer schedule corresponding to a portion for a certain substrate after unloading of the certain substrate from the first processing tank, wherein the certain substrate is determined to have the estimated process end time that is behind the scheduled transfer start time, a second part of the transfer schedule corresponding to a non-transferred portion for one or a plurality of substrates on an upstream side that are affected by transfer of the certain substrate, and a third part of the transfer schedule for one or a plurality of subsequent unprocessed substrates that are still placed in a substrate container, from the transfer schedule; corrects the scheduled transfer start time to the estimated process end time; and reinserts the first part, the second part and the third part into the transfer schedule, in accordance with the corrected scheduled transfer start time, so as to adjust the transfer schedule.

11. The apparatus for processing the substrate according to claim 9,
wherein in a case where, after an actual process end time which is a time point when all the one or plurality of processes in the first processing tank were terminated, it is determined that the actual process end time is beyond the scheduled transfer start time, the controller corrects the scheduled transfer start time to a time determined by adding a predetermined time period to the actual process end time and adjusts the transfer schedule.

12. The apparatus for processing the substrate according to claim 11,
wherein the controller once excludes a first part of the transfer schedule corresponding to a portion for a certain substrate after unloading of the certain substrate from the first processing tank, wherein the certain substrate is determined to have the actual process end time that is beyond the scheduled transfer start time, a second part of the transfer schedule corresponding to a non-transferred portion of one or a plurality of substrates on an upstream side that are affected by transfer of the certain substrate, and a third part of the transfer schedule for one or a plurality of subsequent unprocessed substrates that are still placed in a substrate container, from the transfer schedule; corrects the scheduled transfer start time to the time determined by adding the predetermined time period to the actual process end time; and reinserts the first part, the second part and the third part into the transfer schedule, in accordance with the corrected scheduled transfer start time, so as to adjust the transfer schedule.

13. The apparatus for processing the substrate according to claim 9
wherein the controller calculates the estimated process end time by a rule-based calculation formula or a learnt network using the detection value of the sensor.

14. The apparatus for processing the substrate according to claim 9,
wherein the controller generates and adjusts the transfer schedule by using a graph network-type scheduler, a simulation-type scheduler or a machine learning-type scheduler.

15. The apparatus for processing the substrate according to claim 9,
wherein the first process is a plating process, and
the one or plurality of processes include a plating process alone or a plating process and a rinse process.

16. A method of controlling an apparatus for processing a substrate, which comprises a plurality of processing tanks, each being configured to perform processing of a substrate; and a transfer machine configured to transfer the substrate, wherein the plurality of processing tanks include a first processing tank configured such that one or a plurality of processes including a first process are performed for the substrate therein,
the method of controlling the apparatus for processing the substrate comprising:
generating a transfer schedule, which causes the substrate to be transferred between the plurality of processing tanks and to be processed, and controlling the transfer of the substrate by the transfer machine and controlling the processing of the substrate in each of the plurality of processing tanks, based on the transfer schedule; and
adding a positive or negative margin time to a processing time of the first process that is set in a recipe to generate the transfer schedule, wherein the margin time is calculated by a learning network or a statistical calculation method using actually measured processing times obtained by actually performing the first process with regard to a plurality of substrates in the first processing tank.

17. A storage medium configured to store therein a program that causes a computer to perform a method of controlling an apparatus for processing a substrate, which comprises a plurality of processing tanks, each being configured to perform processing of a substrate; and a transfer machine configured to transfer the substrate, wherein the plurality of processing tanks include a first processing tank configured such that one or a plurality of processes including a first process are performed for the substrate therein,
wherein the program causes the computer to perform:
generating a transfer schedule, which causes the substrate to be transferred between the plurality of processing tanks and to be processed, and controlling the transfer of the substrate by the transfer machine and controlling the processing of the substrate in each of the plurality of processing tanks, based on the transfer schedule; and
adding a positive or negative margin time to a processing time of the first process that is set in a recipe to generate the transfer schedule, wherein the margin time is calculated by a learning network or a statistical calculation method using actually measured processing times obtained by actually performing the first process with regard to a plurality of substrates in the first processing tank.

18. A method of controlling an apparatus for processing a substrate, which comprises a plurality of processing tanks, each being configured to perform processing of a substrate; and a transfer machine configured to transfer the substrate, wherein the plurality of processing tanks include a first processing tank, which is configured such that one or a plurality of processes including a first process are performed for the substrate therein and which is provided with a sensor configured to detect a degree of progress of the first process,
the method of controlling the apparatus for processing the substrate comprising:
generating a transfer schedule, which causes the substrate to be transferred between the plurality of processing tanks and to be processed, and controlling the transfer of the substrate by the transfer machine and controlling the processing of the substrate in each of the plurality of processing tanks, based on the transfer schedule; and
estimating an estimated process end time, which is a time point when all the one or the plurality of processes performed in the first processing tank are terminated, from a detection value obtained from the sensor, and when it is determined that the estimated process end time is behind a scheduled transfer start time set in the transfer schedule, correcting the scheduled transfer start time to the estimated process end time and adjusting the transfer schedule.

19. A storage medium configured to store therein a program that causes a computer to perform a method of controlling an apparatus for processing a substrate, which comprises a plurality of processing tanks, each being configured to perform processing of a substrate; and a transfer machine configured to transfer the substrate, wherein the plurality of processing tanks include a first processing tank, which is configured such that one or a plurality of processes including a first process are performed for the substrate therein and which is provided with a sensor configured to detect a degree of progress of the first process,
wherein the program causes the computer to perform:
generating a transfer schedule, which causes the substrate to be transferred between the plurality of processing tanks and to be processed, and controlling the transfer of the substrate by the transfer machine and controlling the processing of the substrate in each of the plurality of processing tanks, based on the transfer schedule; and
estimating an estimated process end time, which is a time point when all the one or the plurality of processes performed in the first processing tank are terminated, from a detection value obtained from the sensor, and when it is determined that the estimated process end time is behind a scheduled transfer start time set in the transfer schedule, correcting the scheduled transfer start time to the estimated process end time and adjusting the transfer schedule.
